(19) United States
(12) Patent Application Publication
(10) Pub. No.: US 2006/0134459 A1
(43) Pub. Date: Jun. 22, 2006

(54) OLEDs with mixed-ligand cyclometallated complexes

(76) Inventors: Shouquan Huo, Webster, NY (US); Joseph C. Deaton, Rochester, NY (US)

Correspondence Address: Paul A. Leipold;Patent Legal Staff, Eastman Kodak Company, 343 State Street, Rochester, NY, 14650-2201, US

(21) Appl. No.: 11/015,627

(22) Filed: Dec. 17, 2004

(51) Int. Cl. H01L 51/54; H05B 33/14; C09K 11/06

(52) U.S. Cl. 428/690; 428/917; 313/504; 313/506; 257/E51.044; 546/4; 546/10

(57) ABSTRACT

An OLED device comprising a cathode, an anode, and having located therebetween a light emitting layer containing an emitting compound having formula (I):
(piq)_{b} M ppy (I) wherein piq is a phenylisoquinoline group and ppy is a phenylpyridine group bearing at least one further substituent on the pyridine ring, wherein M is Ir, Rh, Pt, or Pd and b is 2 in the case of Ir and Rh and 1 in the case of Pt and Pd.

### FIELD OF THE INVENTION

The present invention relates to a mixed-ligand cyclometallated organometallic complex and its use in an organic light-emitting diode (OLED) electroluminescent (EL) device to provide desirable electroluminescent properties.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, Vol. 30, pp. 322-334, 1969; and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often >100V.

More recent organic EL devices include an organic EL element consisting of extremely thin layers (e.g. <1.0 μM) between the anode and the cathode. Herein, the term “organic EL element” encompasses the layers between the anode and cathode. Reducing the thickness lowered the resistance of the organic layer and has enabled devices that operate much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by Tang et al (J. Applied Physics, 65, 3610-3616, (1989)). The light-emitting layer commonly consists of a host material doped with a guest material, otherwise known as a dopant. Still further, there has been proposed in U.S. Pat. No. 4,769,292 a four-layer EL element comprising a hole-injecting layer (HIL), a hole-transporting layer (HTL), a light-emitting layer (LEL) and an electron-transporting/injecting layer (ETL). These structures have resulted in improved device efficiency.

Many emitting materials that have been described as useful in an OLED device emit light from their excited singlet state by fluorescence. The excited singlet state can be created when excitons formed in an OLED device transfer their energy to the singlet excited state of the dopant. However, it is generally believed that only 25% of the excitons created in an EL device are singlet excitons. The remaining excitons are triplet, which cannot readily transfer their energy to the dopant to produce the singlet excited state of a dopant. This results in a large loss in efficiency since 75% of the excitons are not used in the light emission process.

Triplet excitons can transfer their energy to a dopant if it has a triplet excited state that is low enough in energy. If the triplet state of the dopant is emissive it can produce light by phosphorescence. In many cases singlet excitons can also transfer their energy to lowest singlet excited state of the same dopant. The singlet excited state can often relax, by an intersystem crossing process, to the emissive triplet excited state. Thus, it is possible, by the proper choice of host and dopant, to collect energy from both the singlet and triplet excitons created in an OLED device and to produce a very efficient phosphorescent emission. The term electrophosphorescence is sometimes used to denote electroluminescence wherein the mechanism of luminescence is phosphorescence. Singlet and triplet states, and fluorescence, phosphorescence, and intersystem crossing are discussed in J. G. Calvert and J. N. Pitts, Jr., Photochemistry (Wiley, New York, 1966) and further discussed in publications by S. R. Forrest and coworkers such as M. A. Baldo, D. F. O'Brian, M. E. Thompson, and S. R. Forrest, Phys. Rev. B, 60, 14422 (1999) and M. A. Baldo and S. R. Forrest, Phys. Rev. B, 62, 10956 (2000). The singular term “triplet state” is often used to refer to a set of three electronically excited states of spin 1 that have nearly identical electronic structure and nearly identical energy and differ primarily in the orientation of the net magnetic moment of each state. A molecule typically has many such triplet states with widely differing energies. As used hereinafter, the term “triplet state” of a molecule will refer specifically to the set of three excited states of spin 1 with the lowest energy, and the term “triplet energy” will refer to the energy of these states relative to the energy of the ground state of the molecule.

One class of useful phosphorescent materials is the transition metal complexes having singlet ground states and triplet excited states. For example, fac-tris(2-phenylpyridinato-N,C^{2′})iridium(III) (Ir(ppy)₃) strongly emits green light from a triplet excited state owing to, first, the large spin-orbit coupling of the heavy atom and, second, to the nature of the lowest excited state which is a charge transfer state having a Laporte-allowed (orbital-symmetry-allowed) transition to the ground state (K. A. King, P. J. Spellane, and R. J. Watts, J. Am. Chem. Soc., 107, 1431 (1985), M. G. Colombo, T. C. Brunold, T. Reidener, H. U. Güdel, M. Fortsch, and H.-B. Bürgi, Inorg. Chem., 33, 545 (1994)). Small-molecule, vacuum-deposited OLEDs having high efficiency have also been demonstrated with Ir(ppy)₃ as the phosphorescent material and 4,4′-N,N′-dicarbazole-biphenyl (CBP) as the host (M. A. Baldo, S. Lamansky, P. E. Burrows, M. E. Thompson, S. R. Forrest, Appl. Phys. Lett., 75, 4 (1999), T. Tsutsui, M.-J. Yang, M. Yahiro, K. Nakamura, T. Watanabe, T. Tsuji, Y. Fukuda, T. Wakimoto, S. Miyaguchi, Jpn. J. Appl. Phys., 38, LI502 (1999)). Further, fac-tris(1-phenylisoquinolinato-N,C^{2′})iridium(III) (Ir(piq)₃) strongly emits red light and has been used as an efficient phosphorescent dopant in OLED devices (A. Tsuboyama et al, J. Am. Chem. Soc. 125, 12971-12979 (2003)). However, Ir(piq)₃ has a high sublimation temperature, which can lead to degradation of the material during vacuum deposition of the OLED device.

LeCloux et al. in International Patent Application WO 03/040256 A2, and Petrov et al. in International Patent Application WO 02/02714 A2 teach additional iridium complexes for electroluminescent devices. Mixed tris-cyclometallated iridium complexes have recently attracted attention, and their applications to OLED devices have been demonstrated (T. Igarashi et al., US 2001/0019782 A1; J. Kamatani et al., US 2003/0068526 A1; and S. Akiyama et al., JP 2003/192691A. However, the synthesis of those mixed ligand complexes is challenging. Therefore, examples of their application to OLED devices are very limited.

It is a problem to be solved to provide new phosphorescent emitting materials that are easily manufacturable, have good sublimation properties, and provide desired colors, good operational stability, and maintain device efficiency.

### SUMMARY OF THE INVENTION

The invention provides an OLED device comprising a cathode, an anode, and having located therebetween a light emitting layer containing an emitting compound having formula (I):
(piq)_{b} M ppy (I)
wherein piq is a phenylisoquinoline group and ppy is a phenylpyridine group bearing at least one further substituent on the pyridine ring, wherein M is Ir, Rh, Pt, or Pd and b is 2 in the case of Ir and Rh and 1 in the case of Pt and Pd. The invention also provides a new organometallic complex.

The OLED device provides useful features such as low sublimation temperature, operating stability, hue, and ease of manufacture.

### BRIEF DESCRIPTION OF THE DRAWINGS

FIG. 1 shows a schematic cross-section of a typical OLED device in which this invention can be used. Since device feature dimensions such as layer thicknesses are frequently in sub-micrometer ranges, the drawings are scaled for ease of visualization rather than dimensional accuracy.

### DETAILED DESCRIPTION OF THE INVENTION

The invention is summarized above.

An emitting compound comprising a light-emitting mixed-ligand organometallic complex has the general formula:
(piq)_{b} M ppy (I)

wherein piq is a phenylisoquinoline group and ppy is a phenylpyridine group bearing at least one substituent on the pyridine group, wherein M is Ir, Rh, Pt, or Pd and b is 2 in the case of Ir and Rh and 1 in the case of Pt and Pd. M is conveniently iridium. The organometallic complex conveniently emits in the red region of the spectrum and desirably has an emission maximum from 615 to 630 nm.

A mixed-ligand compound such as shown in formula (I) has some advantages over homoleptic complexes. For example, the phenylisoquinoline ligand can be selected to provide a triplet energy that provides the desired emission wavelength in an OLED device. The phenylpyridine ligand can be selected to have a higher triplet energy, so that it will not affect the emission wavelength of the complex. The phenylpyridine ligand can likewise be selected to improve stability and efficiency of the complex. Further, since the symmetry of the complex is reduced by replacing one of ligands with a different ligand and the size of this ligand can be controlled, the vacuum deposition temperature can be lowered. This is advantageous in that decomposition of materials can be reduced when it is necessary to maintain the material at the vacuum deposition temperature for a long period of time. Further, the introduction of a substituent to the pyridine ring of the ppy group can block the reactive sites of the pyridine ring, thus improving the stability, and can also fine-tune the device hue to achieve the desired emission properties.

A suitable embodiment of the above formula is shown in Formula II, below.

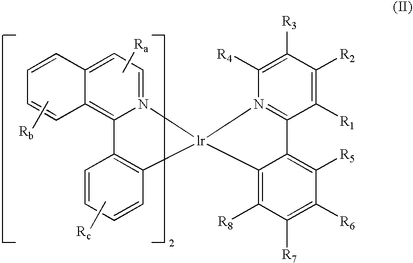

In II, at least one of R₁, R₂, R₃, and R₄ is a substituent that is not H. The substituent can be selected from the group consisting of alkyl such as methyl and ethyl group, aryl such as phenyl group, or alkenyl such as vinyl group. More than one of R₁, R₂, R₃, and R₄ can be individually substituted in such a manner. In the case where more than one of R₁, R₂, R₃, and R₄ are substituted, they can form a saturated ring, but not a fused aromatic ring.

The R groups on the phenyl ring of the phenylpyridine group, R₅, R₆, R₇, and R₈, can be individually selected from H, and alkyl, aryl, or alkenyl groups. In the case where more than one of R₅, R₆, R₇, and R₈ are substituted with other than H, they can form a ring that can be saturated or can be aromatic.

The phenylisoquinoline ligand can be unsubstituted, or can be substituted with one or more groups, that is, one or two Rₐ, or from one to four R_{b}, or from one to four R_{c}, or any combination. The substituents on the phenylisoquinoline group, Rₐ, R_{b}, and R_{c}, can be individually selected from alkyl, fluoro, or perfluoroalkyl such as trifluoromethyl.

It is desirable that substituents in the complex be selected so as to achieve a triplet energy for the phenylpyridine group higher than that of the phenylisoquinoline group. It is further desirable that the substitution maintains a lower vaporization temperature under the same vacuum conditions for the complex than for the corresponding homoleptic piq complex. Typically, the latter limits substituents to 24 carbon atoms or less.

The emitting complex can be part of a polymeric compound, e.g. as a side group attached to a polymeric chain (such as polyethylene) or can be part of the polymeric chain itself.

The mixed tris-cyclometallated complexes of this invention can be prepared in accordance with the following schemes:

Preparation of mer-(ppy)₃Ir

Step 1: Preparation of (ppy)₂Ir(μ-Br)₂Ir(ppy)₂ 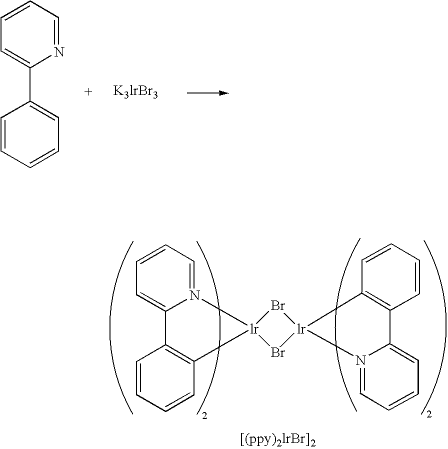
Step 2: Preparation of 2-(2-bromophenyl)pyridine 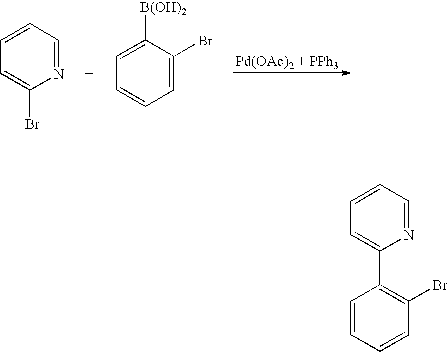
Step 3: Preparation of mer-(ppy)₃Ir

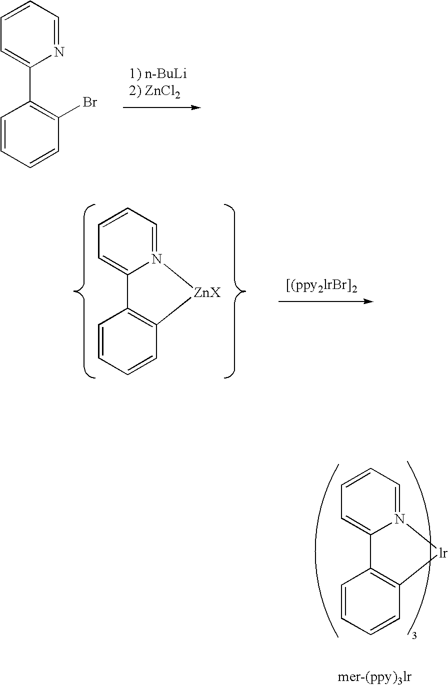

The process centers around the reaction of the organozinc complex with the metal complex to form the organometallic cyclometallated complex (in this case, mer-(ppy)₃Ir). The formation of an organozinc complex (in this case, 2-phenylpyridinato-N,C^{2′}-zinc(II)) can be attained by reaction of a zinc halide with an organolithium compound (which can be prepared by well-known methods and in some cases are commercially available) or with a Grignard reagent (which can be prepared by methods well-known to those skilled in the art) in Step 3. An additional step, which is not required in all cases, is the conversion of an available metal complex bearing a leaving group into a convenient complex (in this case, (ppy)₂Ir(μ-Br)₂Ir(ppy)₂). The organometallic cyclometallated complex can be converted to a different isomer. The following schemes show some non-limiting variations on the basic process with different but analogous materials. Steps that are the same as those in another scheme have been omitted for clarity. It will be understood that further substitution is possible.

Preparation of mer-(pig)Ir(ppy)₂

Step 2: Preparation of 1-(2-bromophenyl)isoquinoline 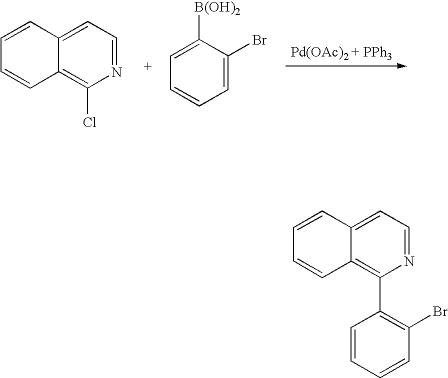
Step 3: Preparation of mer-(piq)Ir(ppy)₂ 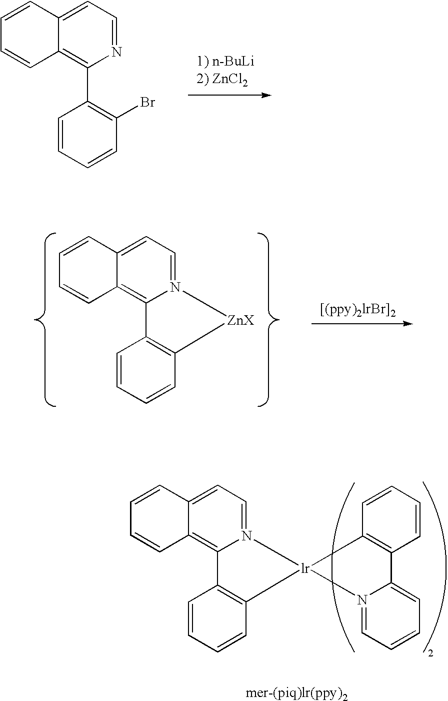
Preparation of mer-(pig)₂Ir(ppy) and fac-(pig)₂Ir(ppy)
Step 3: Preparation of mer-(piq)₂Ir(ppy) 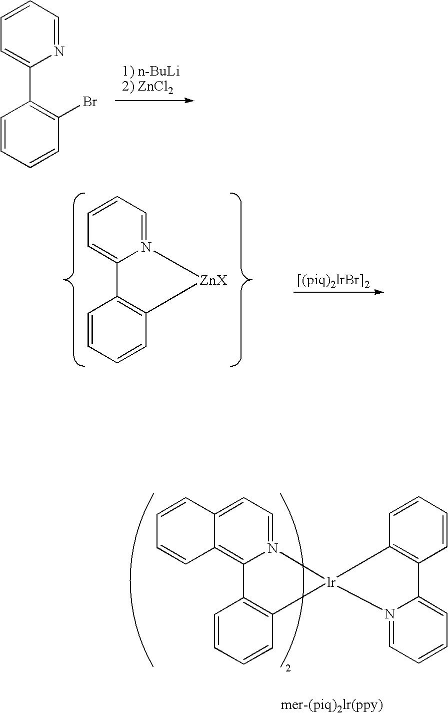
Step 4: Isomerization of mer-(piq)₂Ir(ppy) to fac-(piq)₂Ir(ppy) 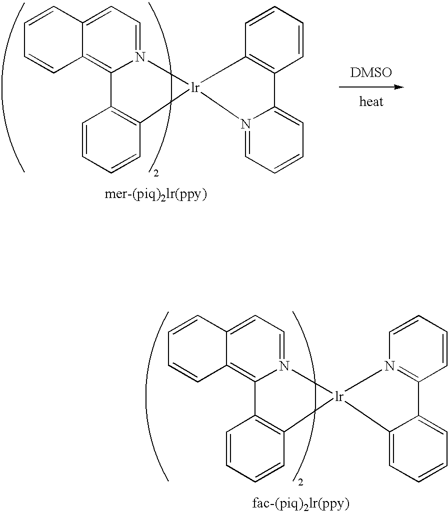
Preparation of mer-(piq)₃Ir
Step 3: Preparation of mer-(piq)₃Ir 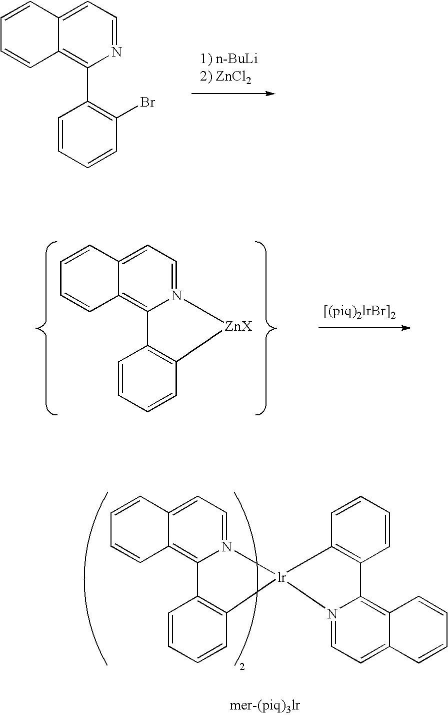
Preparation of (piq)Pt(ppy) 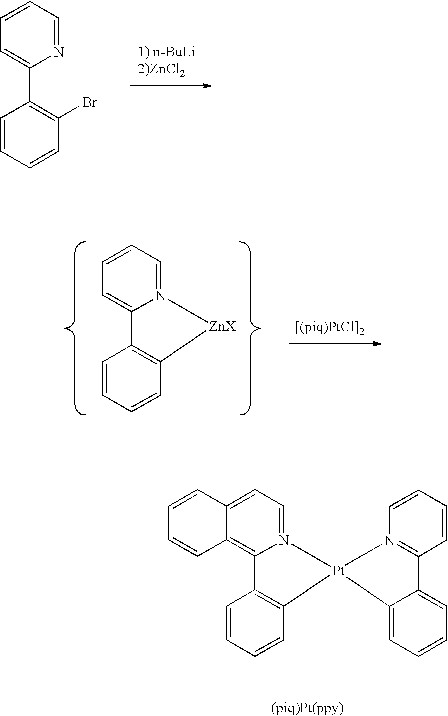
Preparation of Pt(piq)₂

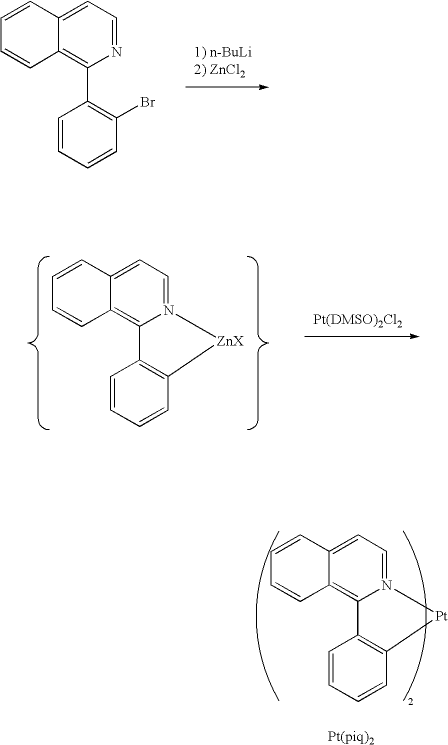

Some non-limiting examples of compounds of this invention are shown below.

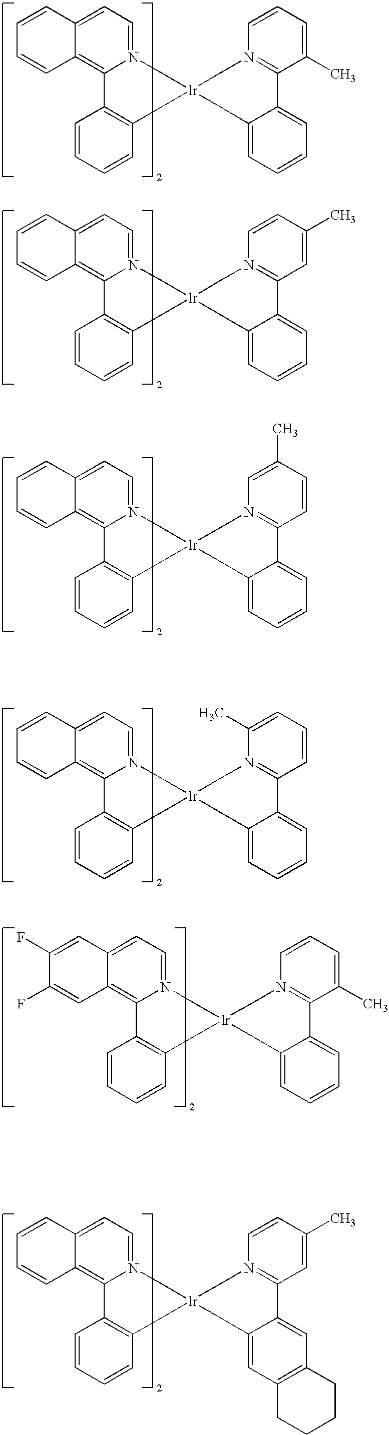

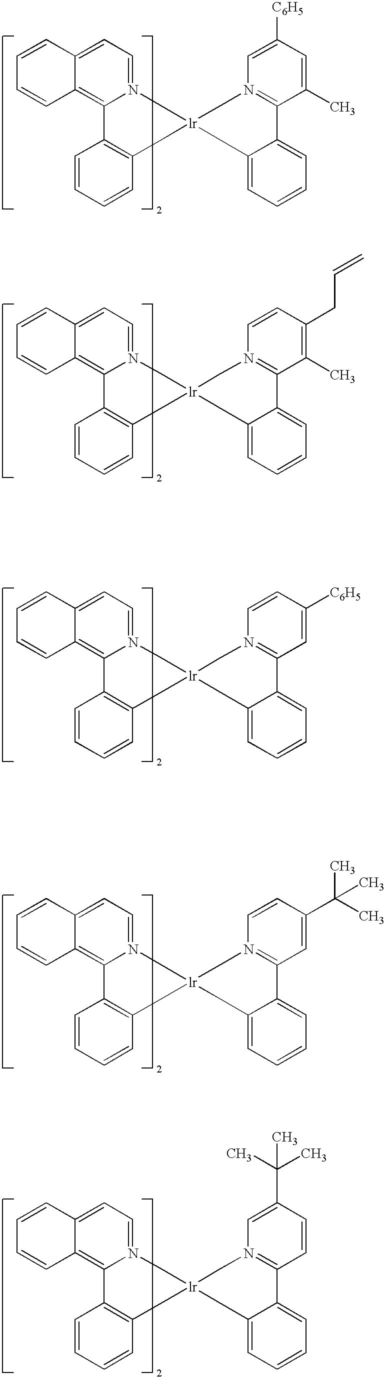

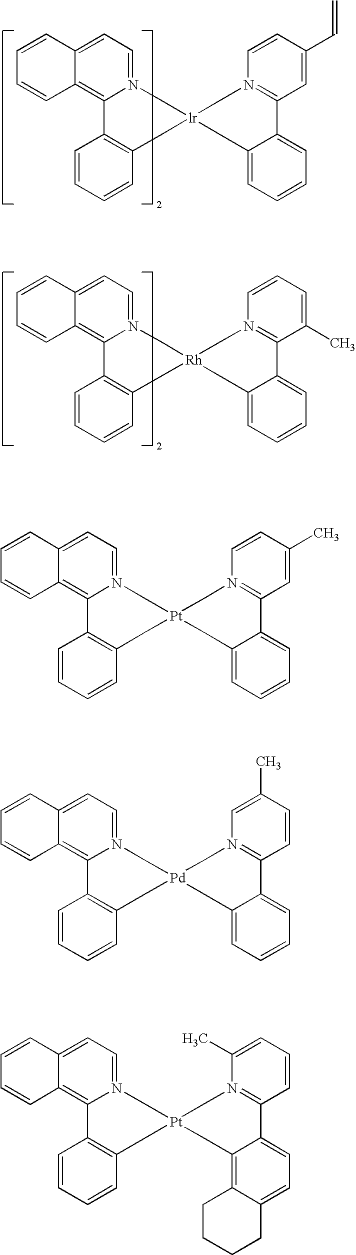

Unless otherwise specifically stated, use of the term “substituted” or “substituent” means any group or atom other than hydrogen. Unless otherwise provided, when a group (including a compound or complex) containing a substitutable hydrogen is referred to, it is also intended to encompass not only the unsubstituted form, but also form further substituted derivatives with any substituent group or groups as herein mentioned, so long as the substituent does not destroy properties necessary for utility. Suitably, a substituent group can be halogen or can be bonded to the remainder of the molecule by an atom of carbon, silicon, oxygen, nitrogen, phosphorous, sulfur, selenium, or boron. The substituent can be, for example, halogen, such as chloro, bromo or fluoro; nitro; hydroxyl; cyano; carboxyl; or groups which can be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which can be substituted and which contain a 3- to 7-membered heterocyclic ring composed of carbon atoms and at least one hetero atom selected from the group consisting of oxygen, nitrogen, sulfur, phosphorous, or boron, such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents can themselves be further substituted one or more times with the described substituent groups. The particular substituents used can be selected by those skilled in the art to attain the desired desirable properties for a specific application and can include, for example, electron-withdrawing groups, electron-donating groups, and steric groups. When a molecule can have two or more substituents, the substituents can be joined together to form a ring such as a fused ring unless otherwise provided. Generally, the above groups and substituents thereof can include those having up to 48 carbon atoms, typically 1 to 36 carbon atoms and usually less than 24 carbon atoms, but greater numbers are possible depending on the particular substituents selected.

General Device Architecture

The present invention can be employed in many OLED device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers can be employed as more fully described hereafter.

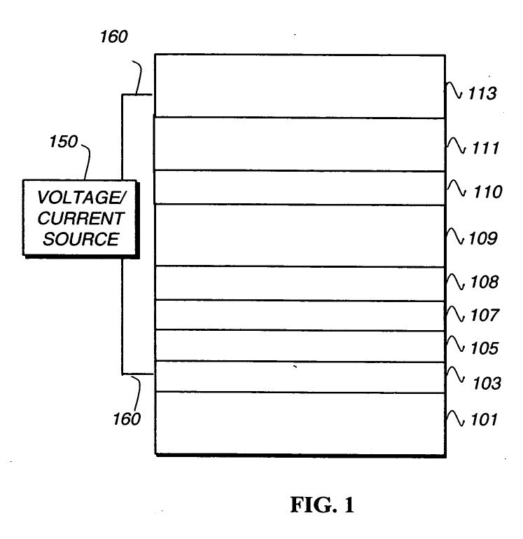

A typical OLED device structure according to the present invention, and especially useful for a small molecule device, is shown in FIG. 1 and is comprised of a substrate 101, an anode 103, a hole-injecting layer 105, a hole-transporting layer 107, an exciton-blocking layer 108, a light-emitting layer 109, a hole-blocking layer 110, an electron-transporting layer 111, and a cathode 113. These layers are described in detail below. Note that the substrate 101 can alternatively be located adjacent to the cathode 113, or the substrate 101 can actually constitute the anode 103 or cathode 113. The organic layers between the anode 103 and cathode 113 are conveniently referred to as the organic EL element. Also, the total combined thickness of the organic layers is desirably less than 500 nm.

The anode 103 and cathode 113 of the OLED are connected to a voltage/current source through electrical conductors. The OLED is operated by applying a potential between the anode 103 and cathode 113 such that the anode 103 is at a more positive potential than the cathode 113. Holes are injected into the organic EL element from the anode 103 and electrons are injected into the organic EL element at the cathode 113. Enhanced device stability can sometimes be achieved when the OLED is operated in an AC mode where, for some time period in the AC cycle, the potential bias is reversed and no current flows. An example of an AC driven OLED is described in U.S. Pat. No. 5,552,678.

Substrate

The OLED device of this invention is typically provided over a supporting substrate 101 where either the cathode 113 or anode 103 can be in contact with the substrate. The electrode in contact with the substrate 101 is conveniently referred to as the bottom electrode. Conventionally, the bottom electrode is the anode 103, but this invention is not limited to that configuration. The substrate 101 can either be light transmissive or opaque, depending on the intended direction of light emission. The light transmissive property is desirable for viewing the EL emission through the substrate 101. Transparent glass or plastic is commonly employed in such cases. The substrate 101 can be a complex structure comprising multiple layers of materials. This is typically the case for active matrix substrates wherein TFTs are provided below the OLED layers. It is still necessary that the substrate 101, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate 101 can be a complex structure comprising multiple layers of materials such as found in active matrix TFT designs. It is necessary to provide in these device configurations a light-transparent top electrode.

Anode

When the desired electroluminescent light emission (EL) is viewed through the anode, the anode 103 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 103. For applications where EL emission is viewed only through the cathode 113, the transmissive characteristics of the anode 103 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes can be polished prior to application of other layers to reduce surface roughness so as to minimize short circuits or enhance reflectivity.

Cathode

When light emission is viewed solely through the anode 103, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)), the cathode being capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. An ETL material doped with an alkali metal, for example, Li-doped Alq, is another example of a useful EIL. Other useful cathode material sets include, but are not limited to, those disclosed in U.S. Pat. Nos. 5,059,861, 5,059,862, and 6,140,763.

When light emission is viewed through the cathode, the cathode 113 must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Hole-Injecting Layer (HIL)

A hole-injecting layer 105 can be provided between anode 103 and hole-transporting layer 107. The hole-injecting material can serve to improve the film formation property of subsequent organic layers and to facilitate injection of holes into the hole-transporting layer 107. Suitable materials for use in the hole-injecting layer 105 include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP 0 891 121 A1 and EP 1 029 909 A1. A hole-injection layer is conveniently used in the present invention, and is desirably a plasma-deposited fluorocarbon polymer. The thickness of a hole-injection layer containing a plasma-deposited fluorocarbon polymer can be in the range of 0.2 to 200 nm and suitably in the range of 0.3 to 15 nm.

Hole-Transporting Layer (HTL)

While not always necessary, it is often useful to include a hole-transporting layer in an OLED device. The hole-transporting layer 107 of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines is those which include at least two aromatic tertiary amine moieties as described in U.S. Pat. No. 4,720,432 and U.S. Pat. No, 5,061,569. Such compounds include those represented by structural formula (A). 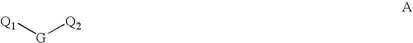
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 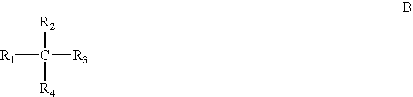
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C): 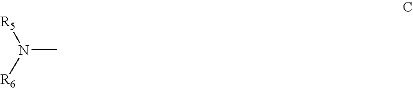
wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by formula (C), linked through an arylene group. Useful tetraaryldiamines include those represented by formula (D). 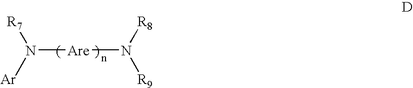
wherein

each Are is an independently selected arylene group, such as a phenylene or anthracene moiety,

n is an integer of from 1 to 4, and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single tertiary amine compound or a mixture of such compounds. Specifically, one can employ a triarylamine, such as a triarylamine satisfying the formula (B), in combination with a tetraaryldiamine, such as indicated by formula (D). When a triarylamine is employed in combination with a tetraaryldiamine, the latter is sometimes positioned as a layer interposed between the triarylamine and the electron injecting and transporting layer. Illustrative of useful aromatic tertiary amines are the following:

1,1-Bis(4-di-p-tolylaminophenyl)cyclohexane (TAPC)

1,1-Bis(4-di-p-tolylaminophenyl)-4-methylcyclohexane

1,1-Bis(4-di-p-tolylaminophenyl)-4-phenylcyclohexane

1,1-Bis(4-di-p-tolylaminophenyl)-3-phenylpropane (TAPPP)

N,N,N′,N′-tetraphenyl-4,4′″-diamino-1,1′:4,1″:4″,1′″-quaterphenyl

Bis(4-dimethylamino-2-methylphenyl)phenylmethane

1,4-bis[2-[4-[N,N-di(p-toly)amino]phenyl]vinyl]benzene (BDTAPVB)

N,N,N′,N′-Tetra-p-tolyl-4,4′-diaminobiphenyl (TTB)

N,N,N′,N′-Tetraphenyl-4,4′-diaminobiphenyl

N,N,N′,N′-tetra-1-naphthyl-4,4′-diaminobiphenyl

N,N,N′,N′-tetra-2-naphthyl-4,4′-diaminobiphenyl

N-Phenylcarbazole

4,4′-Bis[N-(1-naphthyl)-N-phenylamino]biphenyl (NPB)

4,4′-Bis[N-(1-naphthyl)-N-(2-naphthyl)amino]biphenyl (TNB)

4,4′-Bis[N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis[N-(1-naphthyl)-N-phenylamino]naphthalene

4,4′-Bis[N-(9-anthryl)-N-phenylamino]biphenyl

4,4′-Bis[N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis[N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(2-naphthyl)amino]naphthalene

N,N,N′,N′-Tetra(2-naphthyl)-4,4″-diamino-p-terphenyl

4,4′-Bis{N-phenyl-N-[4-(1-naphthyl)-phenyl]amino}biphenyl

2,6-Bis[N,N-di(2-naphthyl)amino]fluorene

4,4′,4″-tris[(3-methylphenyl)phenylamino]triphenylamine (MTDATA)

4,4′-Bis[N-(3-methylphenyl)-N-phenylamino]biphenyl (TPD)

Another class of useful hole-transporting materials includes polycyclic aromatic compounds as described in EP 1 009 041. Tertiary aromatic amines with more than two amine groups can be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS. It is also possible for the hole-transporting layer to comprise two or more sublayers of differing compositions, the composition of each sublayer being as described above. The thickness of the hole-transporting layer can be between 10 and about 500 nm and suitably between 50 and 300 nm.

Exciton-Blocking Layer (EBL)

In addition to suitable hosts, an OLED device employing a phosphorescent material often includes at least one exciton-blocking layer 108, placed adjacent to light-emitting layer 109 on the anode side, to help confine the electron-hole recombination events and the resulting excitons to the light-emitting layer 109 comprising the host and phosphorescent material. In order to that the exciton-blocking layer be capable of confining triplet excitons, the material or materials of the exciton-blocking layer should have triplet energies that exceed that of the phosphorescent material The exciton-blocking layer 108 must be capable of transporting holes to the light-emitting layer 109.

Depending on the composition of the exciton-blocking layer 108, the mobility of holes can vary from high values around 10⁻² cm²V⁻¹s⁻¹ to values below 10⁻⁷ cm²V⁻¹s⁻¹. Hole mobility is defined loosely as the average velocity of holes when they drift under the influence of an electric field. The value of the hole mobility in an amorphous organic material generally depends on the electric field strength and the temperature. Moreover, even a single measurement in a given sample under given conditions typically exhibits a rather broad distribution of individual velocities, believed to be a consequence of the disordered nature of the material. Therefore, a quantitative statement about the mobility must be based on a specific definition of the experimental measurement and the interpretation used to evaluate the mobility. For purposes of this disclosure, the mobility of holes is evaluated in a time-of-flight experiment at room temperature, using a sample of thickness between about 1 and 20 μm, an electric field strength of 1×10⁵ V/cm, and defining the average velocity by the crossing-of tangents method. An example of the experimental measurement technique and the crossing-of-tangents method is provided by J. X. Mack et al., Phys. Rev. B 39, 7500 (1989). Additional information on hole mobility is provided by P. M. Borsenberger and D. S. Weiss, Organic Photoreceptors for Xerography (Marcel Dekker, New York 1998).

The exciton-blocking layer can be between 1 and 300 nm thick and suitably between 10 and 300 nm thick. Thicknesses in this range are relatively easy to control in manufacture. If the exciton-blocking layer 108 is much thicker than 10 nm, it is desirable that the mobility of holes in this layer be relatively high in order to minimize the drive voltage of the device. As is well known from the theory of space-charge-limited currents, a low hole mobility results in the presence of space charge in such a layer when a hole current is driven through it, and the result is a high electric field and a large voltage drop across the layer. Generally speaking, if the exciton-blocking layer is no thicker than about 100 nm, a hole mobility of about 1×10⁻⁴ cm²V⁻¹s⁻¹ is desirable to minimize the drive voltage, but a further increase in the mobility cannot further diminish the drive voltage by more than about 1V. If the exciton-blocking layer is thin, that is <10 nm, a high hole mobility is less important for purposes of minimizing the drive voltage. However, and surprisingly, we have found that the luminous yield and power efficiency of an OLED device employing a phosphorescent material can be increased by use of certain hole-transporting materials in the exciton-blocking layer. The hole-transporting materials are characterized by extremely high values of the hole mobility and, in addition, high triplet energies. Thus, the exciton-blocking layer of the present invention includes a hole-transporting material with a triplet energy exceeding the triplet energy of the phosphorescent material and a hole mobility of at least 1×10⁻³ cm²V⁻¹s⁻¹. This hole-transporting material can comprise certain of the hole-transporting materials described above. Conveniently included are compounds containing one or more triarylamine groups wherein no multiple-ring (e.g. biphenyl, terphenyl) or fused-ring (e.g. naphthalene, fluorene) systems are attached simultaneously to the nitrogen atoms of two or more triarylamine groups and wherein the triplet energy exceeds that of the phosphorescent material. The use of these materials also results in a decreased drive voltage. Examples of materials useful in the exciton-blocking layer 109 include, but are not limited to:
4,4′,4″-tris[(3-methylphenyl)phenylamino]triphenylamine (MTDATA)
4,4′,4″-tris(diphenylamino)triphenylamine (TDATA)
4,4′,4″-tris(carbazol-9-yl)triphenylamine
1,3-Bis(carbazol-9-yl)cyclobutane
1,1-Bis(4-di-p-tolylaminophenyl)cyclohexane (TAPC)
1,1-Bis(4-di-p-tolylaminophenyl)-4-phenylcyclohexane
1,1-Bis(4-di-p-tolylaminophenyl)-4-methylcyclohexane
1,1-Bis(4-di-p-tolylaminophenyl)-3-phenylpropane

An exemplary material that satisfies the above structural and hole-mobility requirements of the present invention is TAPC. The triplet energy is approximately equal to that of the structurally related compound, triphenylamine, namely 3.0 eV (S. L. Murov, I. Carmichael, and G. L. Hug, Handbook of Photochemistry, 2^{nd} ed. (Marcel Dekker, New York, 1993)). The triplet energy of a green phosphorescent material is typically less than 2.5 eV, and lower when the characteristic phosphorescence is yellow, orange, or red. Thus, TAPC meets the requirement that the triplet energy of the exciton-blocking layer exceed that of the phosphorescent material in this invention. The hole mobility in TAPC, under the conditions stated above, is about 7×10⁻³ cm²V⁻¹s⁻¹ (P. M. Borsenberger, J. Chem. Phys. 94, 8276 (1991)) and therefore meets the requirements of the present invention. Additional materials that satisfy the above structural, triplet-energy, and hole-mobility requirements of the present invention are 1,1-bis(4-di-p-tolylaminophenyl)-4-phenylcyclohexane 1,1-bis(4-di-p-tolylaminophenyl)-4-methylcyclohexane, and 1,1-bis(4-di-p-tolylaminophenyl)-3-phenylpropane. An example of a material that fails to satisfy the structural requirements is NPB. The hole mobility in NPB, under the conditions stated above, is about 5×10⁴ cm²V⁻¹s⁻¹ (B. Chen et al., Jpn. J. Appl. Phys. 39, 1190 (2000)) and also fails to meet the requirements of the present invention.

Exciton-blocking layer 108 can be used alone or with a known hole-transporting layer 107.

An exciton-blocking layer as described here has been found to provide improved efficiency. In one embodiment, an exciton-blocking layer is used with a light-emitting layer comprising a phosphorescent light-emitting material and a host for the light-emitting material, and a hole-injecting layer adjacent to the anode. Conveniently, the hole-injecting layer includes a plasma-deposited fluorocarbon polymer as described in U.S. Pat. No. 6,208,075. In a further embodiment, an exciton-blocking layer is used with a light-emitting layer comprising a phosphorescent light-emitting material and a host for the light-emitting material, and a hole-blocking layer 110 on the cathode side of the light-emitting layer.

Light-Emitting Layer (LEL)

Suitably, the light-emitting layer 109 of the OLED device comprises a mixture of a host material and one or more guest materials for emitting light. At least one of the guest materials is suitably a phosphorescent complex comprising an organometallic compound as described by structure (I) above. The light-emitting guest material(s) is typically present in an amount of from 1 to 15 wt % of the host, and conveniently from 2 to 6 wt % of the host. For convenience, the phosphorescent complex guest material may be referred to herein as a phosphorescent material. Usefully, many of the herein-described phosphorescent organometallic materials emit in the red region of the spectrum, that is, with a maximum emission in the range of 580 to 700 nm, and suitably from 615 to 630 nm.

Phosphorescent materials of Formula 1 can be used in combination with other phosphorescent materials, either in the same or different layers. The term phosphorescent materials herein means materials that emit light from a triplet excited state. Some other phosphorescent materials are described in WO 00/57676; WO 00/70655; WO 01/41512 A1; WO 02/15645 A1; US 2003/0017361 A1; WO 01/93642 A1; WO 01/39234 A2; U.S. Pat. No. 6,458,475 B1; WO 02/071813 A1; U.S. Pat. No. 6,573,651 B2; US 2002/0197511 A1; WO 02/074015 A2; U.S. Pat. No. 6,451,455 B1; US 2003/0072964 A1; US 2003/0068528 A1; U.S. Pat. No. 6,413,656 B1; U.S. Pat. No. 6,515,298 B2; U.S. Pat. No. 6,451,415 B1; U.S. Pat. No. 6,097,147; US 2003/0124381 A1; US 2003/0059646 A1; US 2003/0054198 A1; EP 1 239 526 A2; EP 1 238 981 A2; EP 1 244 155 A2; & US 2002/0100906 A1; US 2003/0068526 A1; US 2003/0068535 A1; JP 2003073387A; JP 2003/073388A; US 2003/0141809 A1; US 2003/0040627 A1; JP 2003/059667A; JP 2003/073665A; and US 2002/0121638 A1.

One useful embodiment of a phosphorescent light-emitting material is in a second light-emitting layer (not shown) that emits light of a complementary color-in this case in the blue-green region-so as to provide a white-light-emitting OLED device.

Suitable host materials for phosphorescent materials should be selected so that transfer of a triplet exciton can occur efficiently from the host material to the phosphorescent material but cannot occur efficiently from the phosphorescent material to the host material. Therefore, it is highly desirable that the triplet energy of the phosphorescent material be lower than the triplet energy of the host. Generally speaking, a large triplet energy implies a large optical bandgap. However, the band gap of the host should not be chosen so large as to cause an unacceptable barrier to injection of charge carriers into the light-emitting layer and an unacceptable increase in the drive voltage of the OLED. Suitable host materials are described in WO 00/70655 A2; 01/39234 A2; 01/93642 A1; 02/074015 A2; 02/15645 A1, and US 2002/0117662. Suitable hosts include certain aryl amines, triazoles, indoles, metal-chelated oxinoid compounds, and carbazole compounds. Examples of desirable hosts are bis(8-quinolinolato)(4-phenylphenolato)aluminum (III) (BAlQ-7), bis(8-quinolinolato)(2,6-diphenylphenolato)aluminum (III) (BAlQ-13), 4,4′-bis(carbazol-9-yl)biphenyl (CBP), 2,2′-dimethyl-4,4′-bis(carbazol-9-yl)biphenyl, m-bis(carbazol-9-yl)benzene, and poly(N-vinylcarbazole), including their derivatives.

Desirable host materials are capable of forming a continuous film. The light-emitting layer can contain more than one host material in order to improve the device's film morphology, electrical properties, light emission efficiency, and lifetime. The light emitting layer can contain a first host material that has good hole-transporting properties, and a second host material that has good electron-transporting properties.; The thickness of the light-emitting layer can be between 2 and 100 nm and is suitably between 5 and 50 nm.

Fluorescent Light-Emitting Materials and Layers (LEL)

In addition to the phosphorescent materials of this invention, other light emitting materials can be used in the OLED device, including fluorescent materials. Although the term “fluorescent” is commonly used to describe any light emitting material, in this case we are referring to a material that emits light from a singlet excited state. Fluorescent materials can be used in the same layer as the phosphorescent material, in adjacent layers, in adjacent pixels, or any combination. Care must be taken not to select materials that will adversely affect the performance of the phosphorescent materials of this invention. One skilled in the art will understand that concentrations and triplet energies of materials in the same layer as the phosphorescent material or in an adjacent layer must be appropriately set so as to prevent unwanted quenching of the phosphorescence.

One useful embodiment of a fluorescent light-emitting material is in a second light-emitting layer (not shown) that emits light of a complementary color—in this case in the blue-green region—so as to provide a white-light-emitting OLED device.

As more fully described in U.S. Pat. Nos. 4,769,292 and 5,935,721, the light-emitting layer (LEL) of the organic EL element includes a luminescent fluorescent or phosphorescent material where electroluminescence is produced as a result of electron-hole pair recombination. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. Fluorescent emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small-molecule emitting materials can be molecularly dispersed into a polymeric host, or the emitting materials can be added by copolymerizing a minor constituent into a host polymer. Host materials can be mixed together in order to improve film formation, electrical properties, light emission efficiency, operating lifetime, or manufacturability. The host can comprise a material that has good hole-transporting properties and a material that has good electron-transporting properties.

An important relationship for choosing a fluorescent material as a guest emitting material is a comparison of the excited singlet-state energies of the host and the fluorescent material. It is highly desirable that the excited singlet-state energy of the fluorescent material be lower than that of the host material. The excited singlet-state energy is defined as the difference in energy between the emitting singlet state and the ground state. For non-emissive hosts, the lowest excited state of the same electronic spin as the ground state is considered the emissive state.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives, also known as metal-chelated oxinoid compounds (Formula E), constitute one class of useful host compounds capable of supporting electroluminescence, and are particularly suitable for light emission of wavelengths longer than 500 nm, e.g., green, yellow, orange, and red. 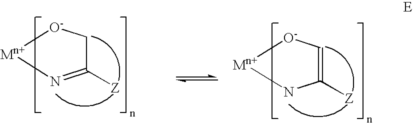
wherein

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; a trivalent metal, such aluminum or gallium, or another metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:

CO-1: Aluminum trisoxine [alias, tris(8-quinolinolato)aluminum(III)]

CO-2: Magnesium bisoxine [alias, bis(8-quinolinolato)magnesium(II)]

CO-3: Bis[benzo {f}-8-quinolinolato]zinc (II)

CO-4: Bis(2-methyl-8-quinolinolato)aluminum(III)-μ-oxo-bis(2-methyl-8-quinolinolato)aluminum(III)

CO-5: Indium trisoxine [alias, tris(8-quinolinolato)indium]

CO-6: Aluminum tris(5-methyloxine) [alias, tris(5-methyl-8-quinolinolato)aluminum(III)]

CO-7: Lithium oxine [alias, (8-quinolinolato)lithium(I)]

CO-8: Gallium oxine [alias, tris(8-quinolinolato)gallium(III)]

CO-9: Zirconium oxine [alias, tetra(8-quinolinolato)zirconium(IV)]

Derivatives of 9,10-di-(2-naphthyl)anthracene (Formula F) constitute one class of useful host materials capable of supporting electroluminescence, and are particularly suitable for light emission of wavelengths longer than 400 nm, e.g., blue, green, yellow, orange or red. 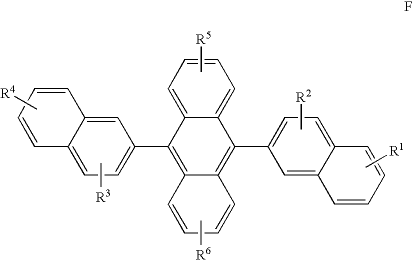
wherein: R¹, R², R³, R⁴, R⁵, and R⁶ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, chlorine, bromine or cyano.

Illustrative examples include 9,10-di-(2-naphthyl)anthracene and 2-t-butyl-9,10-di-(2-naphthyl)anthracene. Other anthracene derivatives can be useful as a host in the LEL, including derivatives of 9,10-bis[4-(2,2-diphenylethenyl)phenyl]anthracene.

Benzazole derivatives (Formula G) constitute another class of useful host materials capable of supporting electroluminescence, and are particularly suitable for light emission of wavelengths longer than 400 nm, e.g., blue, green, yellow, orange or red. 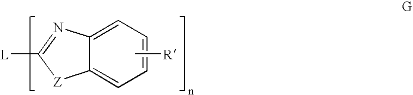
wherein:

n is an integer of 3 to 8;

Z is O, NR or S; and

R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and

L is a linkage unit consisting of alkyl, aryl, substituted alkyl, or substituted aryl, which conjugately or unconjugately connects the multiple benzazoles together. An example of a useful benzazole is 2,2′,2″-(1,3,5-phenylene)tris[1-phenyl-1H-benzimidazole].

Styrylarylene derivatives as described in U.S. Pat. No. 5,121,029 and JP 08333569 are also useful hosts for blue emission. For example, 9,10-bis[4-(2,2-diphenylethenyl)phenyl]anthracene and 4,4′-bis(2,2-diphenylethenyl)-1,1′-biphenyl (DPVBi) are useful hosts for blue emission.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane compounds, and carbostyryl compounds. Illustrative examples of useful materials include, but are not limited to, the following:

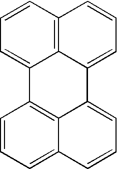

L1

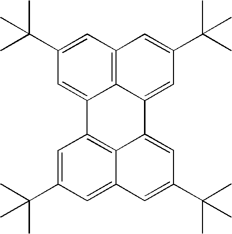

L2

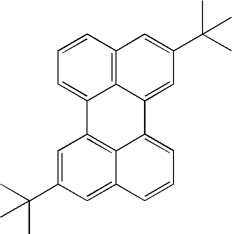

L3

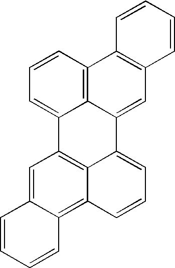

L4

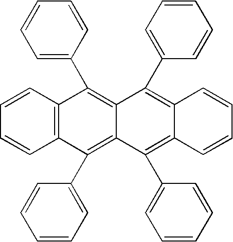

L5

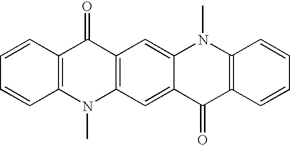

L6

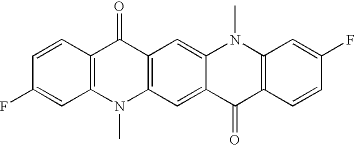

L7

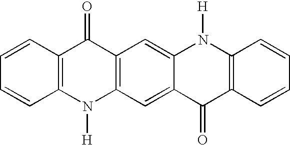

L8

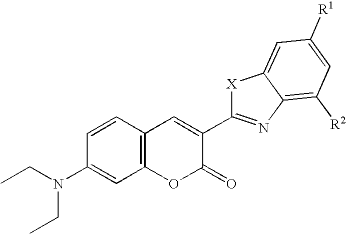

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

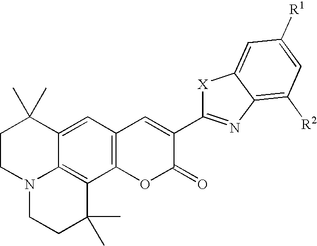

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

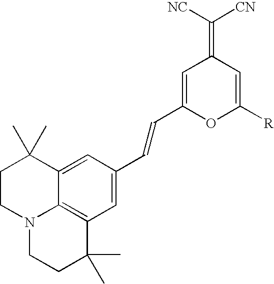

| | R |
|---|---|
| L37 | phenyl |
| L38 | methyl |
| L39 | t-butyl |
| L40 | mesityl |

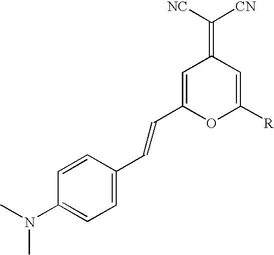

| | R |
|---|---|
| L41 | phenyl |
| L42 | methyl |
| L43 | t-butyl |
| L44 | mesityl |

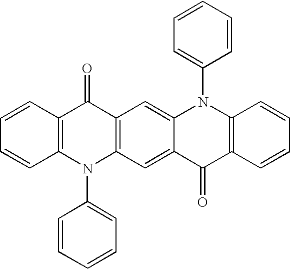

L45

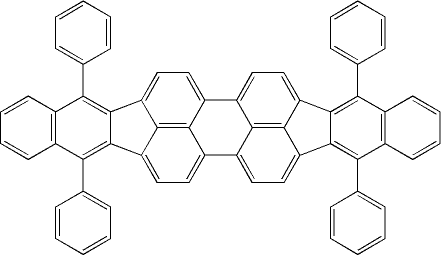

L46

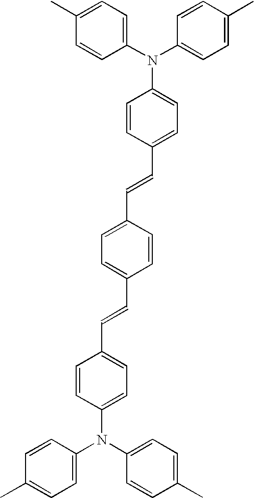

L47

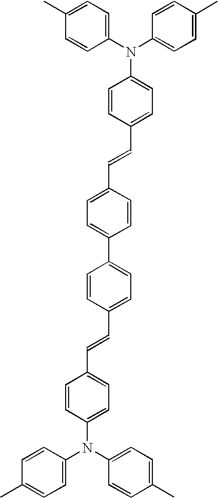

L48

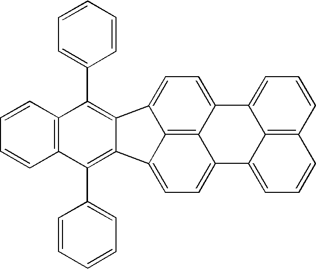

L49

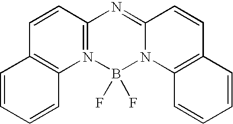

L50

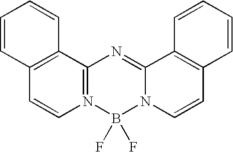

L51

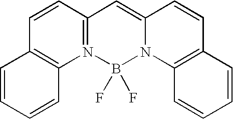

L52

Hole-Blocking Layer (HBL)

In addition to suitable hosts, an OLED device employing a phosphorescent material often requires at least one hole-blocking layer 110 placed between the electron-transporting layer 111 and the light-emitting layer 109 to help confine the excitons and recombination events to the light-emitting layer comprising the host and phosphorescent material. In this case, there should be an energy barrier for hole migration from the host into the hole-blocking layer, while electrons should pass readily from the hole-blocking layer into the light-emitting layer comprising a host and a phosphorescent material. The first requirement entails that the ionization potential of the hole-blocking layer 110 be larger than that of the light-emitting layer 109, desirably by 0.2 eV or more. The second requirement entails that the electron affinity of the hole-blocking layer 110 not greatly exceed that of the light-emitting layer 109, and desirably be either less than that of light-emitting layer or not exceed that of the light-emitting layer by more than about 0.2 eV.

When used with an electron-transporting layer whose characteristic luminescence is green, such as an Alq-containing electron-transporting layer as described below, the requirements concerning the energies of the highest occupied molecular orbital (HOMO) and lowest unoccupied molecular orbital (LUMO) of the material of the hole-blocking layer frequently result in a characteristic luminescence of the hole-blocking layer at shorter wavelengths than that of the electron-transporting layer, such as blue, violet, or ultraviolet luminescence. Thus, it is desirable that the characteristic luminescence of the material of a hole-blocking layer be blue, violet, or ultraviolet. It is further desirable, but not absolutely required, that the triplet energy of the hole-blocking material be greater than that of the phosphorescent material. Suitable hole-blocking materials are described in WO 00/70655A2 and WO 01/93642 A1. Two examples of useful hole-blocking materials are bathocuproine (BCP) and bis(2-methyl-8-quinolinolato)(4-phenylphenolato)aluminum(III) (BAlq). The characteristic luminescence of BCP is in the ultraviolet, and that of BAlq is blue. Metal complexes other than BAlq are also known to block holes and excitons as described in US 2003/0068528. In addition, US 2003/0175553 A1 describes the use of fac-tris(1-phenylpyrazolato-N,C²)iridium(III) (Irppz) for this purpose.

When a hole-blocking layer is used, its thickness can be between 2 and 100 nm and suitably between 5 and 10 nm.

Electron-Transporting Layer (ETL)

Desirable thin film-forming materials for use in forming the electron-transporting layer 111 of the organic EL devices of this invention are metal-chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary of contemplated oxinoid compounds are those satisfying structural formula (E), previously described.

Other electron-transporting materials suitable for use in the electron-transporting layer 111 include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials. Triazines are also known to be useful as electron transporting materials.

If both a hole-blocking layer 110 and an electron-transporting layer 111 are used, electrons should pass readily from the electron-transporting layer 111 into the hole-blocking layer 110. Therefore, the electron affinity of the electron-transporting layer 111 should not greatly exceed that of the hole-blocking layer 110. Preferably, the electron affinity of the electron-transporting layer should be less than that of the hole-blocking layer or not exceed it by more than about 0.2 eV.

If an electron-transporting layer is used, its thickness can be between 2 and 100 nm and suitably between 5 and 20 nm.

Other Useful Organic Layers and Device Architecture

In some instances, layers 109 through 111 can optionally be collapsed into a single layer that serves the function of supporting both light emission and electron transportation. Layers 110 and 111 can also be collapsed into a single layer that functions to block holes or excitons, and supports electron transport. It also known in the art that emitting materials can be included in the hole-transporting layer 107. In that case, the hole-transporting material can serve as a host. Multiple materials can be added to one or more layers in order to create a white-emitting OLED, for example, by combining cyan- and red-emitting materials, or red-, green-, and blue-emitting materials. White-emitting devices are described, for example, in EP 1 187 235, US 2002/0025419, EP 1 182 244, U.S. Pat. No. 5,683,823, U.S. Pat. No. 5,503,910, U.S. Pat. No. 5,405,709, and U.S. Pat. No. 5,283,182 and can be equipped with a suitable filter arrangement to produce a color emission.

This invention can be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation or evaporation, but can be deposited by other means such as coating from a solvent together with an optional binder, to improve film formation. If the material is a polymer, solvent deposition is usually preferred. The material to be deposited by sublimation or evaporation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) or an inkjet method (U.S. Pat. No. 6,066,357).

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOₓ, Teflon, and alternating inorganic/polymeric layers are known in the art for encapsulation.

Optical Optimization

OLED devices of this invention can employ various well-known optical effects in order to enhance their emissive properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color-conversion filters over the display. Filters, polarizers, and anti-glare or anti-reflection coatings can be specifically provided over the cover or as part of the cover.

Embodiments of the invention can provide advantageous features such as better stability and superior color. Embodiments of the organometallic compounds useful in the invention can provide a wide range of hues including those useful in the emission of white light (directly or through filters to provide multicolor displays).

The invention and its advantages can be better appreciated by the following synthetic and device examples.

### EXAMPLES

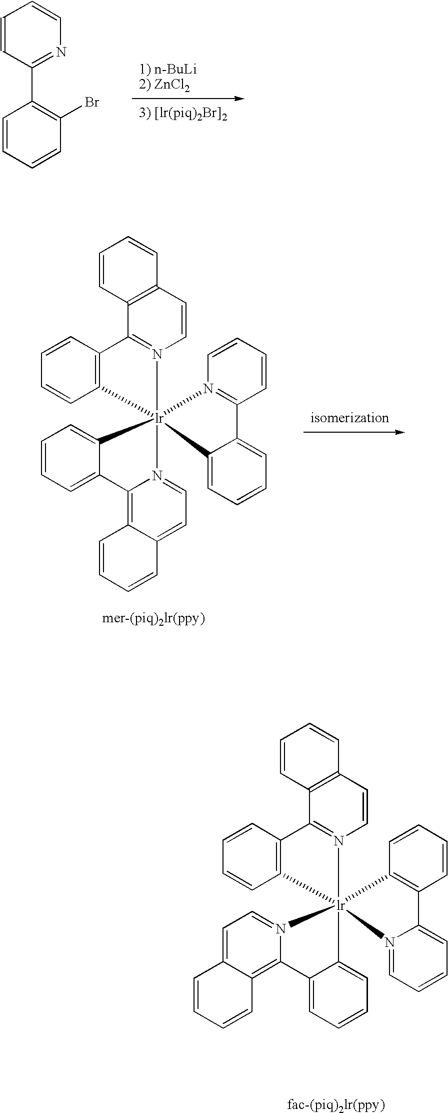

Synthesis of meridional tris-cyclometallated iridium complex, mer-(piq)₂Ir(ppy): A solution of 2-(2-bromophenyl)pyridine (1.8 g, 7.5 mmol) in anhydrous THF (30 mL, Aldrich) was cooled to −78° C. with a dry ice-acetone bath. To this solution was added dropwise a solution of n-BuLi in hexanes (5.2 mL, 1.6 M, 8.3 mmol, Aldrich). The mixture was stirred at −78° C. for 30 min and a solution of ZnCl₂ in ether (7.5 mL, 1.0 M, 7.5 mmol, Aldrich) was added slowly via a syringe. The cooling bath was removed and the reaction mixture was warmed to about room temperature. The bromide-bridged dimer [Ir(piq)₂Br]₂ (2.03 g, 1.5 mmol) was added to the reaction mixture in one portion. Anhydrous dichloromethane (30 mL) was added and the mixture was then brought to reflux. After the mixture was refluxed for 6 hours, any remaining organozinc reagent was quenched with 5 mL of methanol. The mixture was poured into water (200 mL) and extracted with dichloromethane (3×100 mL). The combined organic layers were washed with water (2×100 mL) and brine (200 mL) and dried over MgSO₄. After filtration, the solvents were evaporated and the crude materials were dissolved in a minimum amount of hot dichloromethane. Addition of methanol led to the precipitation of the product, which was collected by filtration, washed thoroughly with methanol and diethyl ether, and dried in air to yield a yellow orange solid, meridional bis-(1-phenylisoquinoline-N,C^{2′})(phenylpyridinato-N,C^{2′}) iridium (III), 1.85 g, 82%. The meridional structure of the compound was confirmed by X-ray crystal structure analysis.

Isomerization of meridional tris-cyclometallated iridium complex, mer-(piq)₂Ir(ppy): A mixture of mer-(piq)₂Ir(ppy) (300 mg, 0.4 mmol), dichloromethane (30 mL), acetic acid (48 mg, 0.8 mmol), and silica gel (2 g, 60-200 mesh, Aldrich) was stirred at room temperature for 24 h. The mixture was filtered through a short column packed with silica gel, and the column was washed with dichloromethane. The filtrate was concentrated, and the addition of methanol led to precipitation of the product. The precipitates were collected by filtration, washed with methanol and ether, and dried in air to yield 110 mg of facial bis-(1-phenylisoquinoline-N,C^{2′})(phenylpyridinato-N,C^{2′}) iridium (III) ((piq)₂Ir(ppy)), 37%,>98% HPLC isomeric purity. The material was sublimed at 270° C. to give deep red crystals with >99% HPLC isomeric purity. A single crystal was selected for X-ray structure analysis, which confirmed the facial arrangement of the three nitrogen donors in the complex.

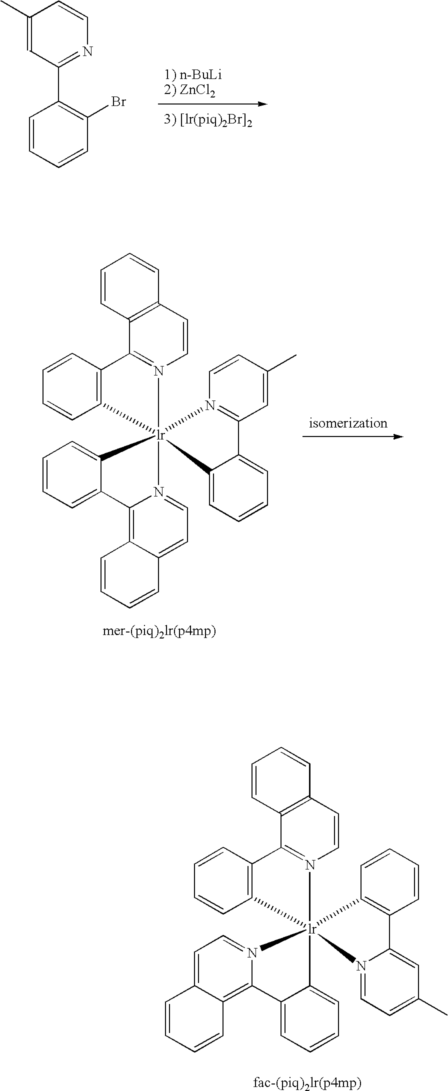

Synthesis of fac-(piq)₂Ir(p4mq): mer-(piq)₂Ir(p4mp): A solution of 2-(2-bromophenyl)-4-methylpyridine (1.0 g, 4 mmol) in anhydrous THF (16 mL, Aldrich) was cooled to −78° C. with a dry ice-acetone bath. To the solution was added dropwise a solution of n-BuLi in hexanes (2.8 mL, 1.6 M, 4.5 mmol, Aldrich). The mixture was stirred at −78° C. for 30 min and a solution of ZnCl₂ in ether (4 mL, 1.0 M, 4 mmol, Aldrich) was added slowly via a syringe. The cooling bath was removed and the reaction mixture was warmed to about room temperature. The bromide-bridged dimer [Ir(piq)₂Br]₂ (crude, 1.33 g, 1.0 mmol) was added to the reaction mixture in one portion and the mixture was brought to reflux. After the mixture was refluxed for 6 hours, the precipitates were collected by filtration, washed with small amount of THF, and dried in air, 0.78 g. Additional product was obtained from the filtrate, 0.15 g. Total 0.93 g, 60%, meridional bis-(1-phenylisoquinoline-N,C^{2′})(2-phenyl-4-methylpyridinato-N,C^{2′}) iridium (III). The meridional isomer was converted into its facial isomer by treating with acetic acid and silica gel in dichloromethane as described for the synthesis of fac-(piq)₂Ir(ppy).

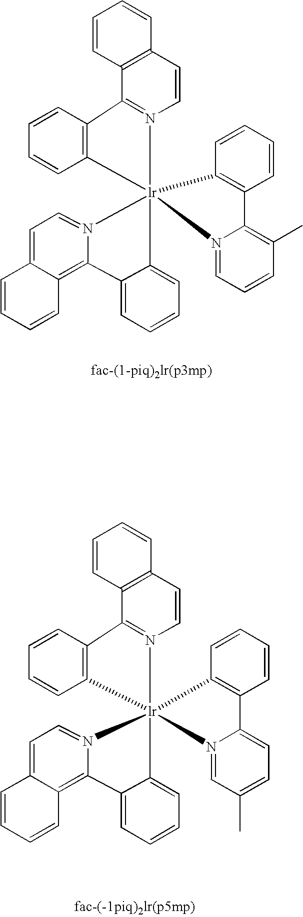

Mixed tris-cyclometallated iridium compounds, fac-(piq)2Ir(p3mp) and fac-(piq)₂Ir(p5mp), were prepared in a similar manner to that for the preparation of fac-(piq)₂Ir(ppy).

### Device 1 (Inventive Example)

An EL device (Device 1) satisfying the requirements of the invention was constructed in the following manner:
1. A glass substrate, coated with an approximately 85 nm layer of indium-tin oxide (ITO) as the anode, was sequentially ultrasonicated in a commercial detergent, rinsed in deionized water, degreased in toluene vapor and exposed to oxygen plasma for about 1 minute.
2. Over the ITO was deposited a 1 nm fluorocarbon (CFx) hole-injecting layer (HIL) by plasma-assisted deposition of CHF₃.
3. A hole-transporting layer (HTL) of N,N′-di-1-naphthyl-N,N′-diphenyl-4,4′-diaminobiphenyl (NPB) having a thickness of 75 nm was then evaporated from a resistance-heated tantalum boat.
4. A 35 nm light-emitting layer (LEL) of 4,4′-bis(carbazol-9-yl)biphenyl (CBP) as a host and fac-bis-(1-phenylisoquinolinato-N,C^{2′})(2-phenyl-4-methyl-pyridinato-N,C^{2′})iridium (III) [i.e., (1-piq)₂Ir(p4mp)] as a guest present at 10 vol % was then deposited onto the hole-transporting layer. These materials were also evaporated from tantalum boats.
5. A hole-blocking layer (HBL) of bis(2-methyl-8-quinolinolato)(4-phenylphenolato)aluminum (III) (BAlq) having a thickness of 10 nm was then evaporated from another tantalum boat.
6. A 40 nm electron-transporting layer (ETL) of tris(8-quiriolinolato)aluminum (III) (Alq) was then deposited onto the light-emitting layer. This material was also evaporated from a tantalum boat.
7. On top of the Alq layer was deposited a 220 nm cathode formed of a 10:1 volume ratio of Mg and Ag.

The above sequence completed the deposition of the EL device. The device, together with a desiccant, was then hermetically packaged in a dry glove box for protection against ambient environment.

### Device 2 (Comparative Example)

A comparative EL device (Device 2) was fabricated in an identical manner to Device 1 except that in the light-emitting layer fac-(1-piq)₂Ir(ppy) was the guest.

The cells thus formed were tested for efficiency, stability, and color at an operating current density of 20 mA/cm² and the results are reported in Table 1 in the form of luminance efficiency, power efficiency, % luminance remaining after fade, and CIE (Commission Internationale de l'Eclairage) coordinates.

TABLE 1
Evaluation Results for EL devices.

| | | Efficiency | Luminance | | | |
|---|---|---|---|---|---|---|
| Device | Guest material | (W/A) | % After 300 hr | CIEx | CIEy | Type |
| 1 | fac-(1-piq)₂Ir(p4mp) | 0.137 | 86 | 0.672 | 0.326 | Invention |
| 2 | fac-(1-piq)₂Ir(ppy) | 0.146 | 65 | 0.664 | 0.332 | Comparison |

As can be seen from Table 1, the EL device incorporating the inventive emitter fac-(1-piq)₂Ir(p4mp) demonstrated higher stability than the comparative emitter fac-(1-piq)₂Ir(ppy) while maintaining similar efficiency.

### Devices 3-5 (Inventive Examples)

Device 3 was fabricated in the identical manner to Device 1 except that in Step 3 the hole-transporting layer (HTL) had a thickness of 115 nm, and in Step 4 the emitter fac-(1-piq)₂Ir(p4mp) was used at 4% level, and the host material comprised NPB (15%) and bis(8-quinolinolato)(2,6-diphenylphenolato)aluminum (III) (BAlQ-13). The temperature necessary to deposit the dopant at the desired rate at the 4% level was also measured.

Device 4 was fabricated in an identical manner to Device 3 except that in Step 4 emitter material fac-(1-piq)₂Ir(p3mp) was used.

Device 5 was fabricated in an identical manner to Device 3 except that in Step 4 emitter material fac-(1-piq)₂Ir(p5mp) was used.

### Device 6 (Comparative Example)

Comparative example Device 6 was fabricated in an identical manner to Device 3 except that emitter material fac-(1-piq)₂Ir(ppy) was used.

The cells thus formed for Devices 3 to 6 were tested for efficiency, stability, and color at an operating current density of 20 mA/cm² and the results are reported in Table 1 in the form of luminance efficiency, power efficiency, % luminance remaining after fade, and CIE coordinates

TABLE 2
Evaluation Results for EL devices.

| | | Efficiency | Luminance | | | |
|---|---|---|---|---|---|---|
| Device | Guest material | (W/A) | % After 300 hr | CIEx | CIEy | Type |
| 3 | fac-(1-piq)₂Ir(p4mp) | 0.180 | 92 | 0.664 | 0.332 | Invention |
| 4 | fac-(1-piq)₂Ir(p3mp) | 0.178 | 89 | 0.649 | 0.340 | Invention |
| 5 | fac-(1-piq)₂Ir(p5mp) | 0.171 | 93 | 0.662 | 0.334 | Invention |
| 6 | fac-(1-piq)₂Ir(ppy) | 0.183 | 89 | 0.645 | 0.342 | Comparison |

As can be seen from Table 2, the EL device incorporating emitter fac-(1-piq)₂Ir(p4mp) demonstrated superior color retention when changing the host material when compared with that incorporating the comparative emitter fac-(1-piq)₂Ir(ppy) (that is, when comparing the change from Device 1 to Device 3 vs. the change from Device 2 to Device 6). Stability and efficiency were both maintained.

Further, the lower deposition temperature of fac-(1-piq)2Ir(ppy) relative to fac-(1-piq)₃Ir was also maintained by the materials of this invention as shown by the data in Table 3 recording the temperatures required to deposit the quest materials at the same concentration in device fabrication. Thus the materials of this invention show good stability, good efficiency, and good color properties in OLED devices, and also good vaporization properties.

TABLE 3
Temperatures required for vapor deposition of Ir
complexes at equal rates in device fabrication.

| | Deposition Temperature | |
|---|---|---|
| Guest material | (° C.) | Type |
| fac-(1-piq)₂Ir(p4mp) | 299 | Invention |
| fac-(1-piq)₂Ir(p3mp) | 292 | Invention |
| fac-(1-piq)₂Ir(p5mp) | 299 | Invention |
| fac-(1-piq)₂Ir(ppy) | 298 | Comparison |
| fac-(1-piq)₃Ir | 335 | Comparison |

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### PARTS LIST

101 Substrate
103 Anode
105 Hole-Injecting layer (HIL)
107 Hole-Transporting layer (HTL)
108 Exciton-blocking layer (EBL)
109 Light-Emitting layer (LEL)
110 Hole-blocking layer (HBL)
111 Electron-Transporting layer (ETL)
113 Cathode
150 Voltage/Current Source
160 Electrical Conductors

1. An OLED device comprising a cathode, an anode, and having located therebetween a light emitting layer containing an emitting compound having formula (I):
(piq)_{b} M ppy (I)
wherein piq is a phenylisoquinoline group and ppy is a phenylpyridine group bearing at least one further substituent on the pyridine ring, wherein M is Ir, Rh, Pt, or Pd and b is 2 in the case of Ir and Rh and 1 in the case of Pt and Pd.

2. The OLED device of claim 1 wherein the further substituent on the pyridine ring of the phenylpyridine group is selected from the group consisting of alkyl, aryl, and alkenyl groups, provided that the further substituent is selected so that the triplet energy of the ppy ligand is higher than that of the piq ligand.

3. The OLED device of claim 2 wherein the phenylpyridine group includes a phenyl group as the further substituent on the pyridine ring.

4. The OLED device of claim 2 wherein the phenylpyridine group includes a methyl group as the further substituent on the pyridine ring.

5. The OLED device of claim 1 wherein the phenylpyridine group also includes one or more substituents on the phenyl group, provided that the substituent on the phenyl group is selected so that the triplet energy of the ppy ligand is higher than that of the piq ligand.

6. The OLED device of claim 5 wherein the one or more substituents on the phenyl group are selected from the group consisting of alkyl, alkenyl, and aryl groups.

7. The OLED device of claim 1 wherein M is iridium.

8. The OLED device of claim 1 wherein the phenylisoquinoline group includes one or more substituents selected from the group consisting of alkyl and fluoro groups, provided that the one or more substituents are selected so that the triplet energy of the ppy ligand is higher than that of the piq ligand.

9. The OLED device of claim 1 wherein the light-emitting layer emits in the red region of the spectrum.

10. The OLED device of claim 9 wherein the light-emitting layer has an emission maximum between 615 and 630 nm.

11. The OLED device of claim 9 further including a second light-emitting layer to provide a white-light-emitting OLED device.

12. The OLED device of claim 11 wherein the second light-emitting layer emits from a singlet excited state.

13. The OLED device of claim 11 wherein the second light-emitting layer emits from a triplet excited state.

14. The OLED device of claim 1 wherein the light-emitting layer comprises a mixture of the emitting compound and a host material.

15. The OLED device of claim 14 wherein the host material is selected from the group consisting of bis(8-quinolinolato)(4-phenylphenolato)aluminum (III) (BAIQ-7), bis(8-quinolinolato)(2,6-diphenylphenolato)aluminum (III) (BAlQ-13), 4,4′-bis(carbazol-9-yl)biphenyl (CBP).

16. The OLED device of claim 14 wherein the emitting compound is present in the amount from 1-15%. in the host material.

17. The OLED device of claim 16 wherein the emitting compound is present in the amount from 2-6% in the host material.

18. The OLED device of claim 1 further including a hole-blocking layer.

19. The OLED device of claim 1 wherein the emitting compound is part of a polymeric compound.

20. The OLED device of claim 19 wherein the emitting compound is a side-group attached to a polymeric chain.

21. The device of claim 1 wherein the emitting compound is represented by Formula II: 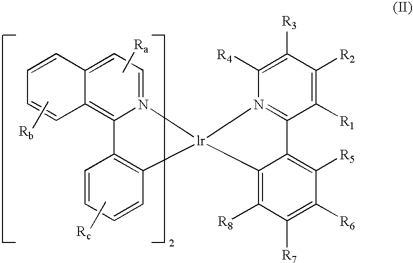
wherein
R¹, R₂, R₃, and R⁴ are independently H or a substituent with at least one being a substituent selected from the group consisting of alkyl, aryl, and alkenyl groups, provided two of R₁, R₂, R₃, and R₄ can join to form a saturated ring;
R₅, R₆, R₇, and R₈, are independently H or a substituent group selected from the group consisting of alkyl, aryl, and alkenyl groups, provided two of R₅, R₆, R₇, and R₈ may join to form a ring; and
Rₐ, R_{b}, and R_{c} independently represent one or more optional alkyl or fluoro groups.

22. The device of claim 21 wherein the emitting compound includes at least one Rₐ, R_{b}, or R_{c} group that is a trifluoromethyl group.

23. The device of claim 21 wherein the emitting compound is represented by one of the following formulas:

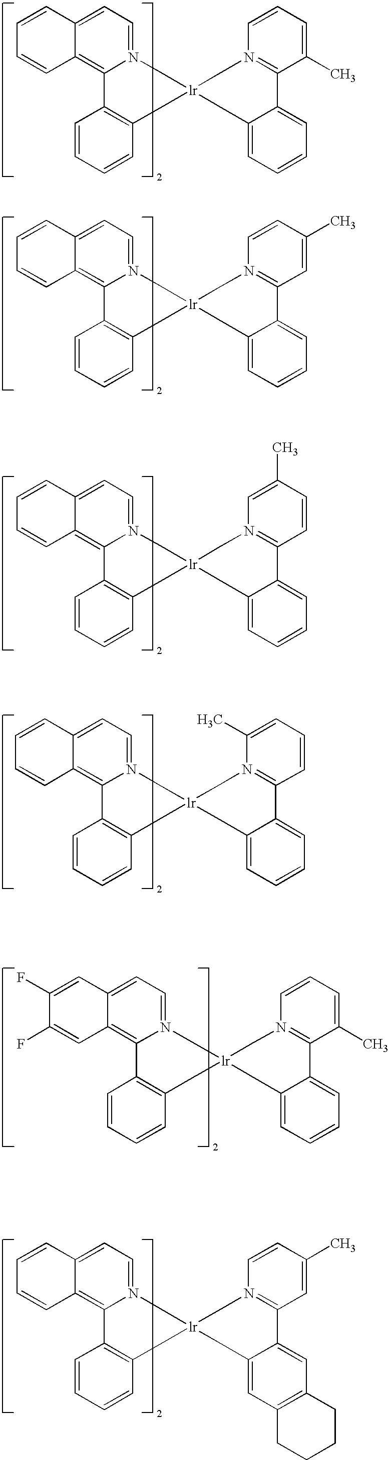

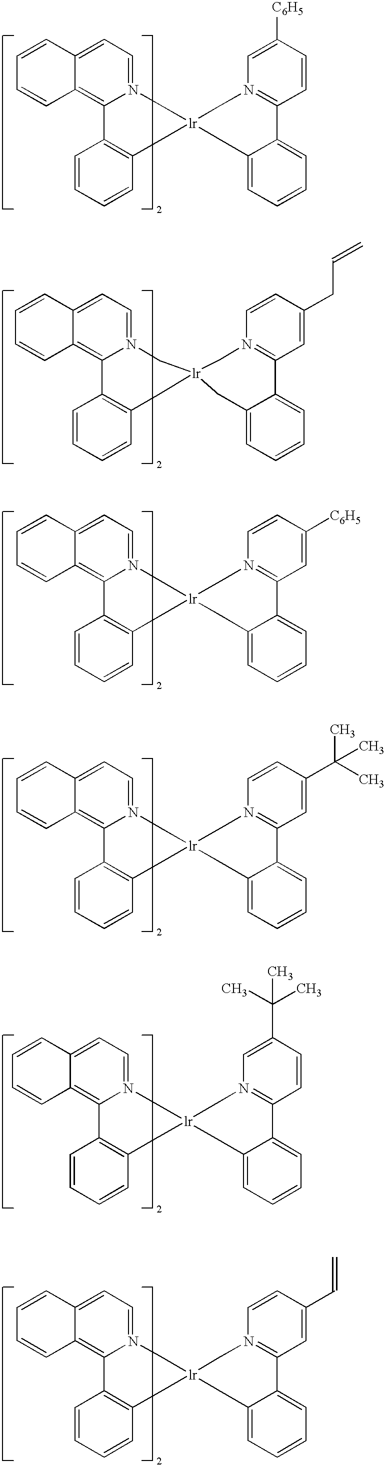

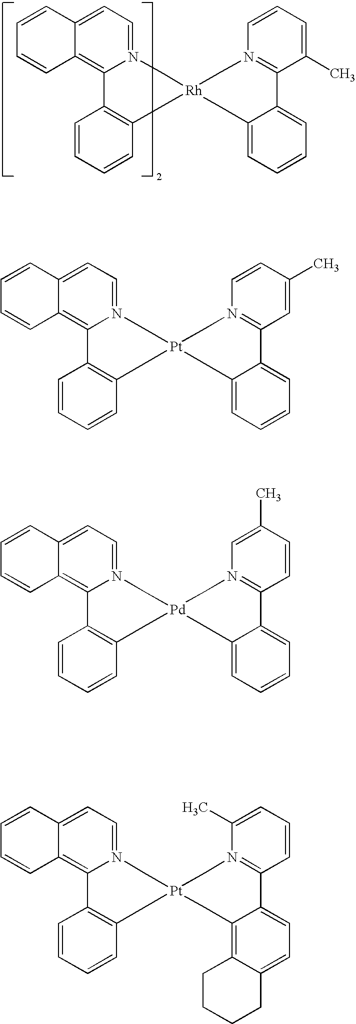

24. An emitting compound having formula (I):
(piq)_{b} M ppy (I)
wherein piq is a phenylisoquinoline group and, ppy is a phenylpyridine group bearing at least one further substituent on the pyridine ring, wherein M is Ir, Rh, Pt, or Pd and b is 2 in the case of Ir and Rh and 1 in the case of Pt and Pd.

25. The emitting compound of claim 24 wherein the at least one further substituent on the pyridine ring of the phenylpyridine group is selected from the group consisting of alkyl, aryl, and alkenyl group, provided that the further substituents are selected so that the triplet energy of the ppy ligand is higher than that of the piq ligand.

26. The emitting compound of claim 25 wherein the phenylpyridine group includes a phenyl group on the pyridine ring.

27. The emitting compound of claim 26 wherein the phenylpyridine group includes a methyl group on the pyridine ring.

28. The emitting compound of claim 24 wherein the phenylpyidine group further includes one or more substituents on the phenyl group, and wherein the substituent is selected so that the triplet energy of the ppy ligand is higher than that of the piq ligand.

29. The emitting compound of claim 28 wherein the one or more substituents are chosen from the group consisting of alkyl, alkenyl, and aryl groups, provided that the substituents are selected so that the triplet energy of the ppy ligand is higher than that of the piq ligand.

30. The emitting compound of claim 24 wherein M is iridium.

31. The emitting compound of claim 24 wherein the phenylisoquinoline group includes one or more substituents selected from the group consisting of alkyl and fluoro groups, provided that the substituents are selected so that the triplet energy of the ppy ligand is higher than that of the piq ligand.
